(19) United States
(12) Patent Application Publication
(10) Pub. No.: US 2026/0150303 A1
(43) Pub. Date: May 28, 2026

(54) DEVICE ARCHITECTURE FOR RESISTIVE RANDOM ACCESS MEMORY

(71) Applicant: HEFEI RELIANCE MEMORY LIMITED, Hefei (CN)

(72) Inventors: Chao-Yang CHEN, Hefei (CN); Wen-Hsiung Chang, Hefei (CN); Zezhi Chen, Hefei (CN)

(21) Appl. No.: 19/084,438

(22) Filed: Mar. 19, 2025

Related U.S. Application Data
(63) Continuation of application No. PCT/CN2024/138716, filed on Dec. 12, 2024.

(30) Foreign Application Priority Data
Nov. 26, 2024 (WO) PCT/CN2024/134493

(51) Int. Cl. H10B 80/00; H10B 63/00

(52) U.S. Cl. CPC H10B 80/00; H10B 63/30

(57) ABSTRACT

An access transistor array for a memory device includes a plurality of active areas (AAs) formed on a substrate. Each AA includes a drain region and a source region arranged in a first direction (Y), with a polysilicon gate (POs) extending in a second direction (X) across the AA and separating the drain and source regions. Adjacent source regions in the second direction are connected, while adjacent drain regions in the second direction are separated by a shallow trench isolation (STI). This configuration reduces the poly-to-poly (PO-to-PO) spacing, decreasing the overall area required for each memory cell and enabling higher memory densities.

### CROSS-REFERENCE TO RELATED APPLICATIONS

This application is a continuation application of International Patent Application No. PCT/CN2024/138716, filed with the China National Intellectual Property Administration on Dec. 12, 2024, which claims the benefit of and priority to International Patent Application No. PCT/CN2024/134493, filed with the China National Intellectual Property Administration on Nov. 26, 2024. The above-referenced applications are incorporated herein by reference in their entirety.

### TECHNICAL FIELD

The present invention relates generally to a new process technique for resistive random-access memory, and more specifically to embedded memory integration technology that reduces bitcell size.

### BACKGROUND

Resistive random-access memory (RRAM) is a type of non-volatile memory where the device resistance can be changed to low resistance state (LRS) or high resistance state (HRS) by applying proper voltage to the device. The difference in resistance (LRS vs HRS) can be utilized to store the digital data “0” and “1”.

In the semiconductor industry, the demand for higher memory density and cost-effective manufacturing processes continues to escalate. One critical factor influencing the economic viability of memory chips is the size of the memory bitcell—the smallest unit of memory that can store one bit of information. Reducing the bitcell size directly impacts the overall chip area, enabling more chips to be fabricated on a single wafer and thereby reducing production costs.

Current RRAM architectures face challenges in minimizing the bitcell size without compromising performance and reliability. Traditional approaches for bitcell size reduction typically use more marginal design or process, for example smaller distance between two devices. This makes the processing more defect prone and thus impact the yield of memory chips.

On the other hand, 3D memory integration presents another layer of complexity. Integrating RRAM with 3D stacking or similar approaches can definitely increase memory density but such process is not mature yet and still require lots of research and development effort.

Therefore, there is a need for an improved RRAM device architecture that addresses these challenges by reducing the bitcell size while maintaining or enhancing performance metrics and chip yield. Such an innovation would contribute to the development of more compact and cost-effective memory chips, aligning with the industry's pursuit of higher density and scalability in non-volatile memory technologies.

### SUMMARY

In one general aspect, an access transistor array may include a plurality of active areas (AA) formed on a substrate, each AA having a drain region and a source region arranged in a first direction (Y), and a polysilicon gate (POs) extending in a second direction (X) across the AA and separating the drain region and source region. The access transistor array may also include connections where adjacent source regions in the second direction are connected, and adjacent drain regions in the second direction are separated by a shallow trench isolation (STI). Other embodiments of this aspect include corresponding computer systems, apparatus, and computer programs recorded on one or more computer storage devices, each configured to perform the actions of the methods.

Implementations may include one or more of the following features. The access transistor array may have each drain region include a drain contact, and adjacent source regions in the second direction share the same source contact. In the access transistor array, drain contacts in adjacent drain regions in the first direction are connected to a bit line, and adjacent source regions in the second direction are connected to the same source contact through a source line. The access transistor array may have a source region length in the first direction smaller than the length of the drain region in the same direction by at least 10%, or by at least 20%. The bit line is perpendicular to the source line. The access transistor array may also have the distance between two adjacent POs sandwiching a source region smaller than the distance between two adjacent POs sandwiching a drain region by at least 10%, or by at least 20%. The access transistor array may serve as a back-end-of-line (BEOL) memory or a resistive random-access memory (RRAM). The source line may connect to a first metal layer in the memory device closest to the substrate. Additionally, the access transistor array may include a word line, where the word line is configured to be parallel to the source line.

In one general aspect, a method may include forming a plurality of active areas on a substrate, each AA having a drain region and a source region arranged in a first direction (Y). The method may also include forming a polysilicon gate (POs) extending in a second direction (X) across the AA, separating the drain region and source region. Additionally, the method may involve forming a shallow trench isolation (STI) extending in the first direction to separate adjacent drain regions in the second direction. The method may further include connecting adjacent source regions in the second direction and separating adjacent drain regions in the second direction with a shallow trench isolation (STI). Furthermore, the method may involve forming a memory device above the substrate. Other embodiments of this aspect include corresponding computer systems, apparatus, and computer programs recorded on one or more computer storage devices, each configured to perform the actions of the methods.

Implementations may include one or more of the following features. The method may include forming a drain contact in each drain region, with a bit line connected to each column of drain contacts in the first direction. Additionally, the method may include forming a source contact for each row of source regions in the second direction and connecting a source line to said row of source regions. Implementations of the described techniques may include hardware, a method or process, or a computer tangible medium.

In one general aspect, an access transistor array may include a plurality of active areas (AA) formed on a substrate, each AA having a drain region and a source region arranged in a first direction (Y), and a polysilicon gate (POs) extending in a second direction (X) across the AA and separating the drain region and source region. The access transistor array may also include connections where adjacent drain regions in the second direction are connected, and adjacent source regions in the second direction are separated by a shallow trench isolation (STI). Each source region may include a source contact, and adjacent drain regions in the second direction may share the same drain contact. Source contacts in adjacent source regions in the first direction are connected to a source line, and adjacent drain regions in the second direction are connected to the same drain contact through a drain line. Implementations of the described techniques may include hardware, a method or process, or a computer tangible medium. Other embodiments of this aspect include corresponding computer systems, apparatus, and computer programs recorded on one or more computer storage devices, each configured to perform the actions of the methods.

### BRIEF DESCRIPTION OF THE DRAWINGS

Non-limiting embodiments of the present invention may be more readily understood by referring to the following drawings.

FIG. 1 is a schematic diagram illustrating an RRAM device architecture commonly used in the industry.

FIG. 2 is a schematic diagram illustrating a novel RRAM device architecture with a shared active area (AA) layout in accordance with embodiments of the present invention.

FIG. 3-6 are schematic diagrams comparing the existing RRAM device architecture with the novel RRAM device architecture featuring the shared AA layout from various perspectives, in accordance with embodiments of the present invention.

FIG. 7 is schematic diagrams illustrating layers in the novel RRAM device architecture featuring the shared AA layout, in accordance with embodiments of the present invention.

FIG. 8 illustrates an example process flow for manufacturing RRAM with the shared AA layout in accordance with embodiments of the present invention.

### DETAILED DESCRIPTION OF THE EMBODIMENTS

Resistive Random Access Memory (RRAM) is an emerging non-volatile memory technology that stores data by changing the resistance of a memory cell. This innovative architecture offers advantages such as high density, low power consumption, and fast switching speeds, making it a promising candidate for future memory applications.

At the core of the RRAM device architecture is the bit cell, which consists of a memory element sandwiched between two electrodes. The memory element typically involves a material whose resistance can be reversibly altered through the application of electrical voltage, enabling it to represent binary data.

Key to the functionality of the RRAM device are several critical components:
Active Area (AA): This is the region within the semiconductor substrate where transistors are formed. These transistors serve as selection devices for the RRAM, enabling or controlling access to the memory cells. The memory switching itself occurs at the RRAM, which is located in the back-end-of-line (BEOL) region of the semiconductor device.
Shallow Trench Isolation (STI): STI structures are used to electrically isolate the Active Areas of adjacent cells.
Polysilicon Gate (Poly or PO): The polysilicon gate controls the flow of current in the underlying transistor associated with each memory cell. By applying a voltage to the gate, it modulates the conductivity of the channel between the source and drain, effectively turning the transistor on or off. This gating mechanism is essential for accessing the memory cell during read and write operations.
Transistor Source and Drain Contacts: These contacts provide the pathways for current to enter and exit the transistor's channel. The transistor source is the terminal where carriers (electrons or holes) enter the channel, while the transistor drain is where they exit.

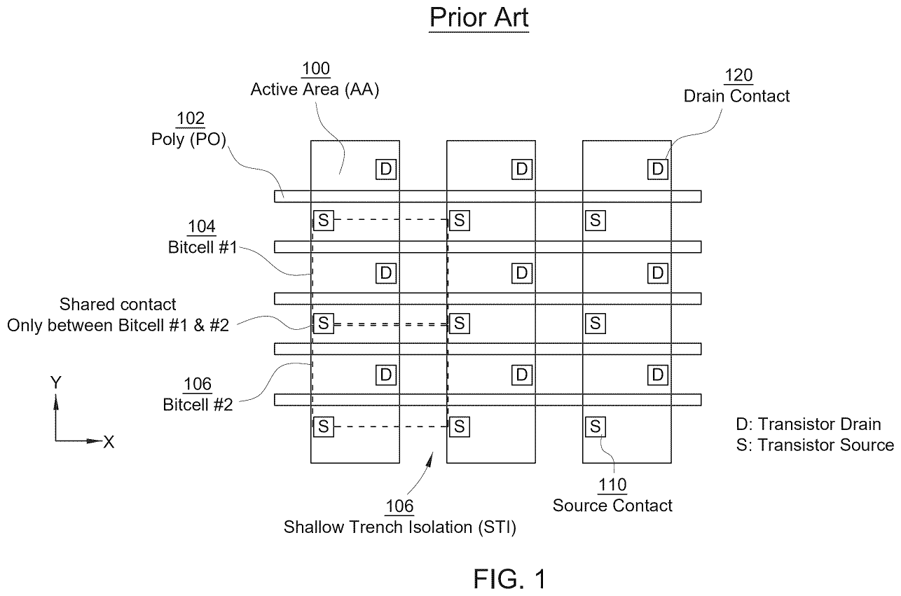

FIG. 1 is a schematic diagram illustrating an RRAM device architecture commonly used in the industry, in which the Active Area (AA) 100 is separated by the Shallow Trench Isolation (STI) 108 in the x-direction. This isolation serve as insulating barrier that prevents electrical interference between adjacent AAs, allowing each memory cell to operate independently without crosstalk or leakage currents affecting neighboring cells.

As shown in FIG. 1, within each Active Area 100, contacts are arranged along the Y-direction in a specific pattern: a drain contact 120, followed by a source contact 110, and then another drain contact 120. This alternating sequence continues throughout the Active Area 100. The drain and source contacts are essential for the operation of the transistors, facilitating the flow of current during read and write operations. In the Y direction, every drain contact 120 is separated from its neighboring source contact(s) 110 by a X-direction polysilicon gate (Poly) 102. These polysilicon gates act as control electrodes for the transistors, and their placement effectively divides each Active Area into distinct drain and source regions. The Polys 102 modulate the conductivity between the drain and source regions, allowing the memory can be either accessed or isolated from other part of circuit.

Each bitcell in this architecture encompasses at least one drain region and one source region, forming the basic unit necessary for data storage and retrieval. As shown in FIG. 1, bitcell #1 (104) and bitcell #2 (106) share the source contact within the same Active Area 100. This shared-source configuration is designed to pack adjacent bitcells densely without compromising their individual functionality. The shared source simplifies the routing of connections and can improve the overall performance of the memory array by reducing the number of required contacts and interconnects.

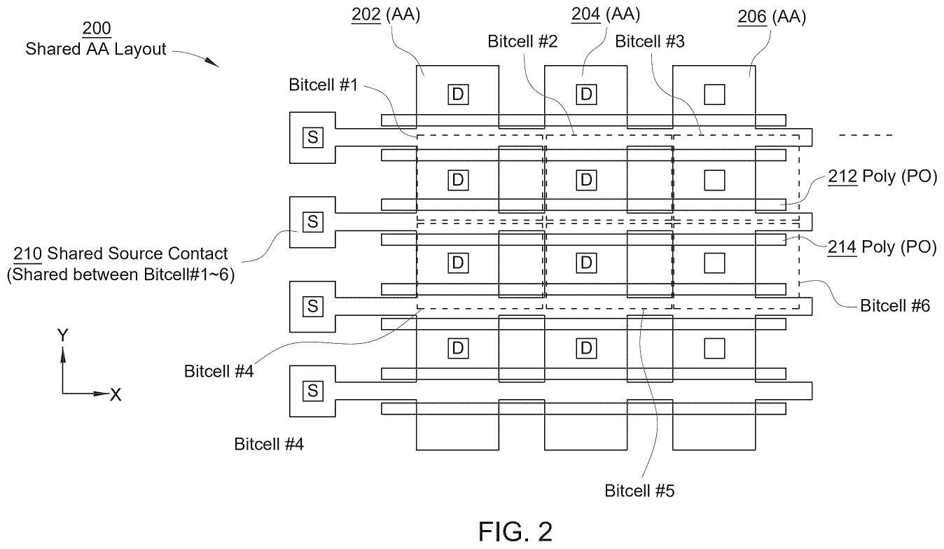

FIG. 2 is a schematic diagram illustrating a novel RRAM device architecture 200 with a shared AA layout in accordance with embodiments of the present invention. In this architecture, the AAs (e.g., 202, 204, and 206) are connected in the x-direction, and a shared source contact 210 located the side of the AAs makes electrical connection to the AAs in the x-direction. This design choice eliminates the need for the source contact within the AAs and between the Poly gates (e.g., 212 and 214).

By relocating the source contact from between the polysilicon gates to the side of the AAs (in the specific example in FIG. 2, the source contact is on the side of AA 202)—while still remaining on the AAs—the poly-to-poly (PO-to-PO) spacing becomes smaller. This allows the transistors to be placed closer together, effectively reducing the distance between adjacent polysilicon gates. The reduction in spacing leads to a more compact layout of the bitcell, decreasing the overall area required for each memory cell.

The shared source contact 210 on the side of the AAs maintains the necessary electrical connectivity for proper transistor operation. Even without the source contact positioned between the polysilicon gates, the transistors function correctly because the connected AAs provides a common pathway for carriers. In the example illustrated in FIG. 2, the source contact 210 is situated on the side of the AAs. It is configured adjacent to the polysilicon gates 212 and 214 and is shared by Bitcells #1 through #6.

By moving the source contacts from between the polysilicon gates to the side of the plurality of AAs, the PO-to-PO distance (e.g., the distance between 212 and 214) is reduced by at least 10% compared to the existing design shown in FIG. 1. This area savings allows for higher memory densities, enabling more bitcells to be packed into the same silicon footprint. The increased density is advantageous for applications requiring large amounts of memory in limited space, such as mobile devices and high-performance computing systems.

Additionally, the shared AA layout in FIG. 2 may lead to improvements in manufacturing efficiency. With fewer source contacts within each individual AA and using a shared source contact across multiple AAs, the overall complexity of the architecture is reduced, which can lead to lower fabrication costs and potentially higher yields due to a decreased likelihood of defects.

Note that the source contact must be made on the AA because it needs to establish an electrical connection with the source region, which is a doped semiconductor region within the AA. Contacts cannot be formed on isolation regions such as the shallow trench isolation (STI); they must be placed on active semiconductor material to ensure proper electrical conductivity. To accommodate the source contact on the side of the AA 202, the AA 202 may be extended or shaped to include extra room on one side. This adjustment allows the source contact to be positioned on the AA 202 but outside the space between the polysilicon gates. By extending the AA 202 in this manner, the source contact remains on the active region of the substrate, maintaining electrical integrity while enabling the reduction of the PO-to-PO spacing between the polysilicon gates.

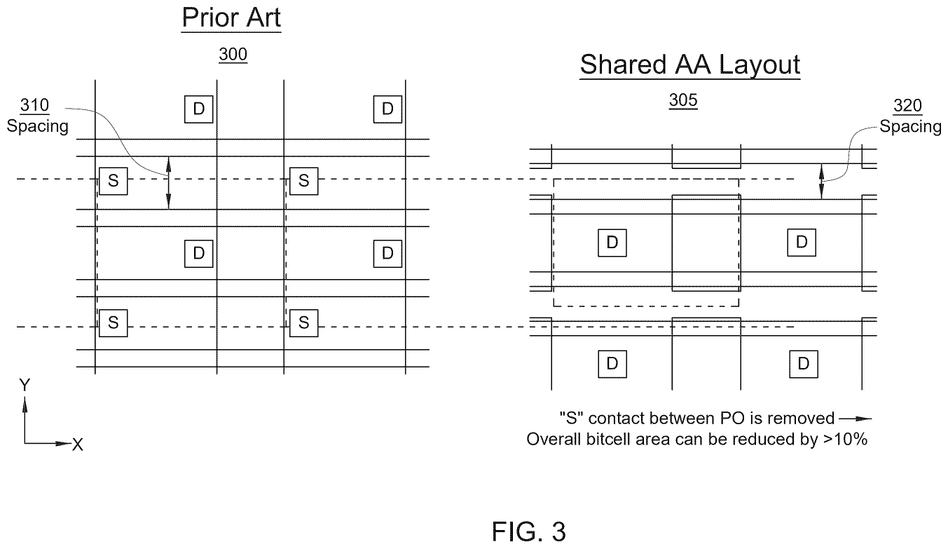

FIG. 3 illustrates a comparison of the bitcell in the prior art 300 (comparable to the prior art illustrated in FIG. 1) and the bitcell in the RRAM device architecture with the shared AA layout 305. The elimination of intra-AA source contacts effectively reduces the spacing between neighboring polysilicon gates (POs); for instance, spacing 310 in the prior art 300 is reduced to spacing 320 in the shared AA layout 305, as shown in FIG. 3. In some embodiments, this reduction in PO-to-PO spacing results in an overall bitcell area reduction of at least 10%. In other embodiments, the bitcell area reduction may be as high as 20% due to the decreased PO-to-PO spacing.

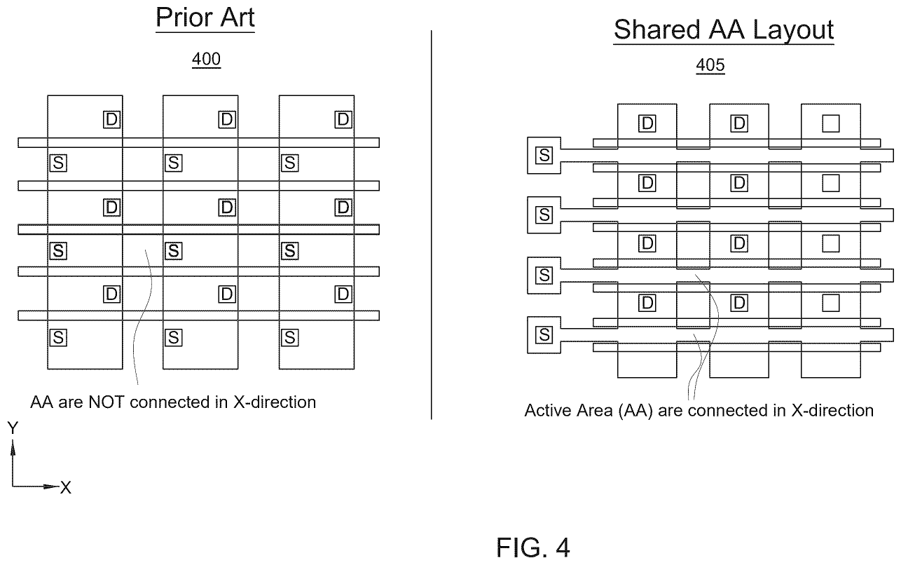

FIG. 4 illustrates another distinction between the prior art 400 (comparable to the prior art illustrated in FIG. 1) and the RRAM device architecture with the shared AA layout 405. In the prior art 400, the AAs are not connected in the x-direction, whereas in the RRAM device architecture with the shared AA layout 405, the AAs are connected in the x-direction with shared source contacts at a side of plurality of AAs.

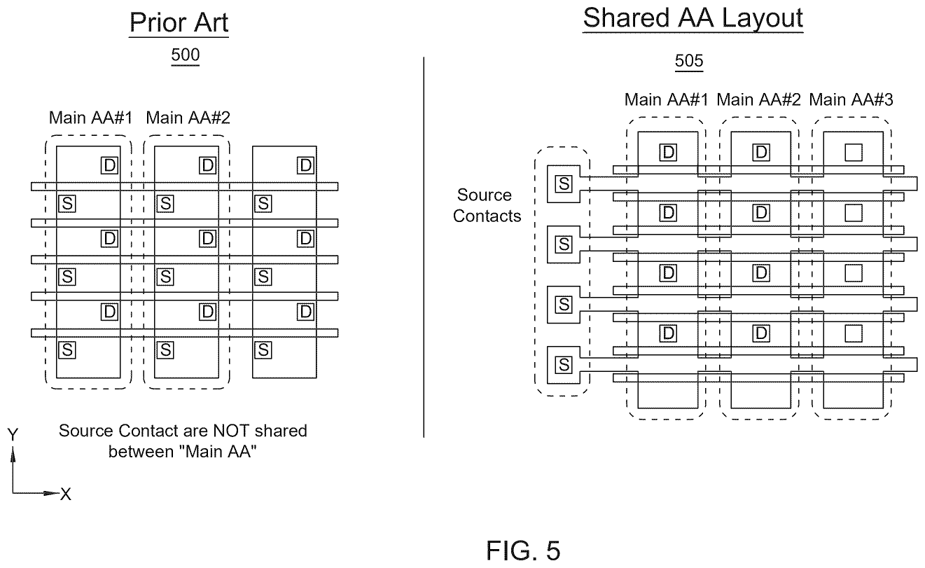

FIG. 5 illustrates yet another difference between the prior art 500 (comparable to the prior art illustrated in FIG. 1) and the RRAM device architecture with the shared AA layout 505. In the prior art 500, the source contacts are distributed in the individual AAs, and are not shared between the AAs (denoted as main AA #1 and main AA #2 in FIG. 5). In contrast, in the RRAM device architecture with the shared AA layout 505, the source contacts are moved to the side of the main AAs and shared by the main AAs in the X-direction.

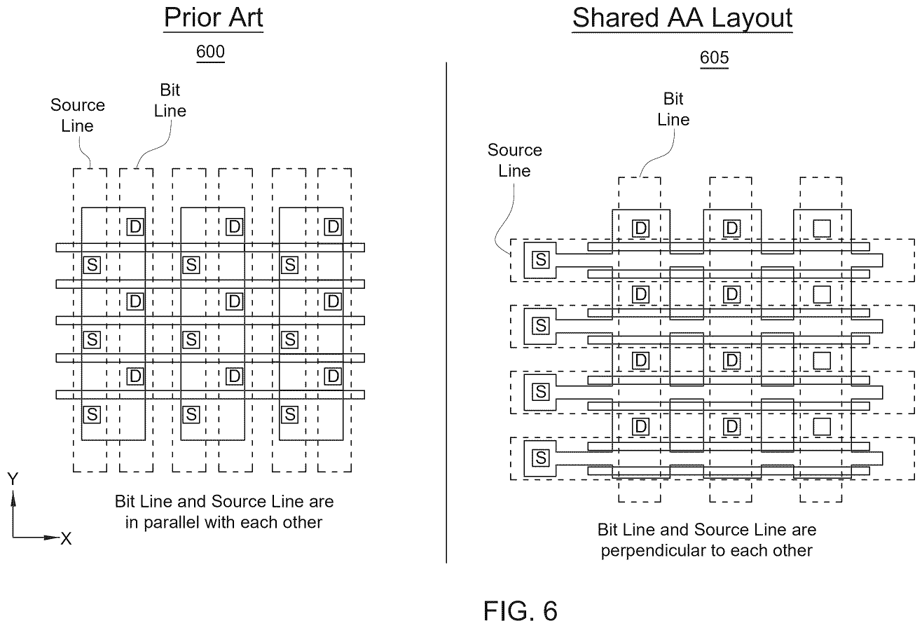

FIG. 6 illustrates yet another distinction between the prior art 600 (comparable to the prior art illustrated in FIG. 1) and the RRAM device architecture with the shared AA layout 605. In the prior art 600, the bitline, which encompasses the drain contacts within individual AAs, and the source line, which encompasses the source contacts within individual AAs, run parallel to each other. For example, in FIG. 6, both the bitline and source line are oriented in the Y direction. In contrast, in the RRAM device architecture with the shared AA layout 605, the bitline and source line are arranged perpendicularly. As illustrated in FIG. 6, the bitline is oriented in the Y direction, while the source line is oriented in the X direction.

Referring back to FIG. 2, the layout illustrated in FIG. 2 represents one embodiment of the novel RRAM device architecture with a shared active area (AA) layout, and it is not the only configuration that achieves the desired technical improvements. A person skilled in the art would appreciate that swapping the drain regions and the source regions can yield similar benefits in reducing the PO-to-PO spacing and reducing the bitcell size.

In the embodiment shown in FIG. 2, the source contacts are moved to the side of the AAs, effectively eliminating the need for source contacts within the AAs and between the POs. This relocation reduces the PO-to-PO spacing by at least 10%, leading to a more compact bitcell layout and higher memory densities. The shared source contact on the side of the AAs maintains the necessary electrical connectivity, ensuring proper transistor operation without compromising performance.

Similarly, an alternative embodiment involves moving the drain contacts out of the AAs while keeping the source contacts within. For instance, an RRAM device may include a plurality of active areas formed on a substrate, each containing a drain region and a source region arranged in a first direction (Y). A polysilicon gate extends in a second direction (X) across each AA, separating the drain and source regions. In this design, adjacent drain regions in the second direction are connected, while adjacent source regions are separated by an STI.

In this alternative embodiment, each source region includes a source contact, and adjacent drain regions in the second direction share the same drain contact. This arrangement allows for the drain contacts to be moved to the side of the AAs, effectively reducing the PO-to-PO spacing in a manner similar to the initial embodiment. The source contacts in adjacent source regions in the first direction are connected to a source line, and the adjacent drain regions in the second direction are connected through a shared drain contact via a drain line.

In this alternative embodiment, the length of the drain region in the first direction is smaller than the length of the source region by at least 10% or even 20%. This intentional dimensional adjustment contributes to the overall reduction in bitcell size, allowing for higher memory densities and more efficient use of the substrate area.

These variations demonstrate the flexibility of the novel RRAM device architecture in optimizing layout efficiency. Whether the source or drain contacts are moved to the side of the AAs, the key objective of reducing the PO-to-PO spacing to minimize the bitcell size is achieved. Adjusting the arrangement and relative dimensions of the drain and source regions, as specified in the claims, allows designers to tailor the architecture to meet specific design requirements or fabrication constraints, further enhancing the competitiveness of RRAM technology.

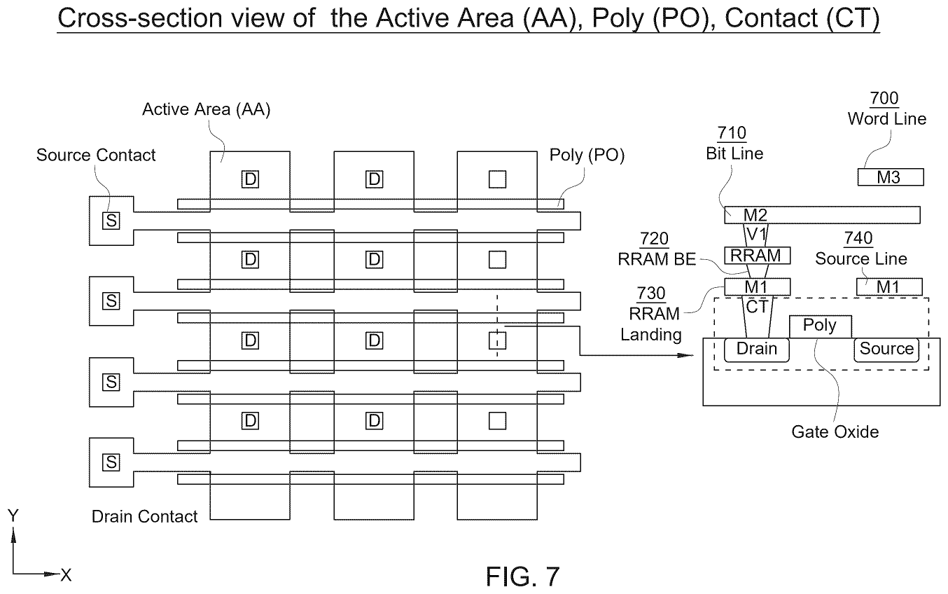

FIG. 7 illustrates a layered view of a RRAM device that utilizes a shared AA layout, and a cross-section view of the AA, Poly, and drain and source regions therein, in accordance with some embodiments.

The RRAM device illustrated in FIG. 7 includes a Word Line 700 at the top layer, which functions as a control line to select memory cells during read and write operations. This line is configured to apply the appropriate voltage levels required to switch the RRAM between its high resistance state (HRS) and low resistance state (LRS).

Beneath the Word Line 700 lies the Bit Line 710, which includes a metal layer M2. This metal layer serves as a conduit for data signals, connecting the RRAM cell to peripheral circuits and enabling the flow of read and write currents. Directly under the metal layer M2 is Via V1, a vertical interconnect that establishes an electrical connection between the Bit Line and the underlying RRAM stack. The use of Via V1 ensures efficient signal transmission and contributes to the compactness of the device by facilitating vertical integration.

The RRAM stack is situated below Via V1 and is the core component responsible for data storage. This stack comprises multiple layers, including a resistive switching layer sandwiched between electrode materials, which together enable the RRAM's ability to toggle between different resistance states. The resistive switching enables the storage of binary information, with the high and low resistance states representing the binary digits “0” and “1.”

Underneath the RRAM stack is the RRAM Bottom Electrode (BE) 720. The BE is essential for providing a stable electrical interface. Below the BE 720 is a metal layer M1 730, labeled as the RRAM landing.

On the same plane as the RRAM landing 730, there are source contacts on metal layer M1 that connect to the source regions formed within the active areas (AAs) on the substrate. These source regions within the AAs act as the source lines and are shared among multiple memory cells. By forming the source lines within the AAs and connecting them via source contacts on M1, the design reduces the need for individual source contacts in each AA, thereby optimizing the layout for higher memory density.

A Contact (CT) connects the metal layer M1 730 (RRAM landing) to the drain region on the semiconductor substrate. The drain region is part of a transistor structure that includes a gate oxide layer and a polysilicon (poly) gate situated between the drain and source regions. The poly gate controls the channel conductivity in the substrate, allowing the transistor to act as a switch that enables or disables the flow of current based on the gate voltage.

The gate oxide layer, positioned directly above the substrate, provides the necessary insulation between the gate electrode and the underlying silicon, ensuring that the gate can modulate the channel without direct electrical contact.

The cross-section of the AA, source region, drain region, and Poly in FIG. 7 are illustrated in the rectangle shape on the layered view of the RRAM device.

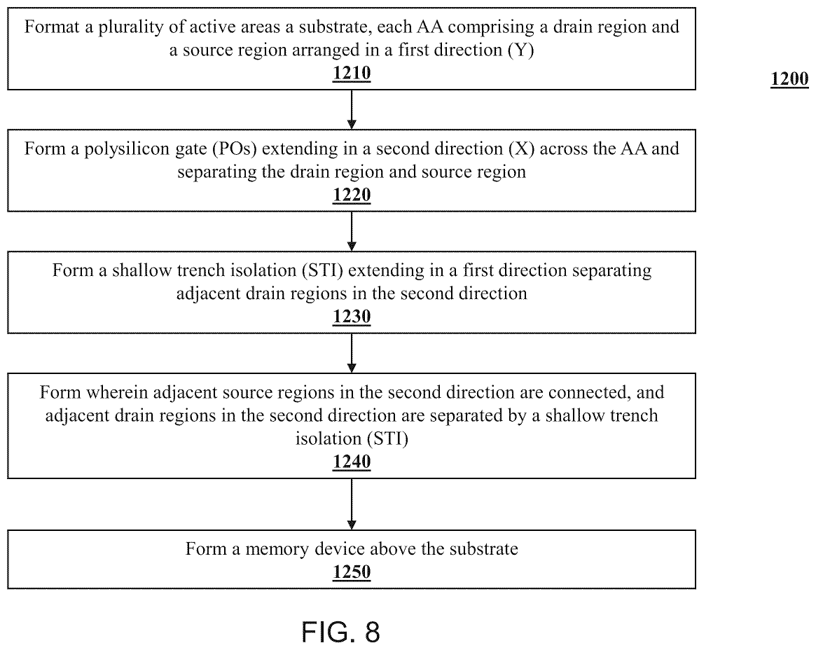

FIG. 8 illustrates an example process flow for manufacturing RRAM with the shared AA layout in accordance with embodiments of the present invention. In some implementations, one or more process blocks of FIG. 8 may be performed by a device.

As shown in FIG. 8, process 1200 may include formatting a plurality of active areas on a substrate, each AA having a drain region and a source region arranged in a first direction (Y) (block 1210). For example, the device may format a plurality of active areas on a substrate, each AA having a drain region and a source region arranged in a first direction (Y), as described above.

As also shown in FIG. 8, process 1200 may include forming a polysilicon gate (POs) extending in a second direction (X) across the AA and separating the drain region and source region (block 1220). For example, the device may form a polysilicon gate (POs) extending in a second direction (X) across the AA and separating the drain region and source region, as described above.

As further shown in FIG. 8, process 1200 may include forming a shallow trench isolation (STI) extending in a first direction separating adjacent drain regions in the second direction (block 1230). For example, the device may form an STI extending in a first direction separating adjacent drain regions in the second direction, as described above.

As also shown in FIG. 8, process 1200 may include forming where adjacent source regions in the second direction are connected, and adjacent drain regions in the second direction are separated by a shallow trench isolation (STI) (block 1240). For example, the device may form where adjacent source regions in the second direction are connected, and adjacent drain regions in the second direction are separated by an STI, as described above.

As further shown in FIG. 8, process 1200 may include forming a memory device above the substrate (block 1250). For example, the device may form a memory device above the substrate, as described above.

Process 1200 may include additional implementations, such as any single implementation or any combination of implementations described below and/or in connection with one or more other processes described elsewhere herein. A first implementation, process 1200 further includes forming a drain contact in each of the drain region, and a bit line connected each column of drain contacts in a first direction.

A second implementation, alone or in combination with the first implementation, process 1200 further includes forming a source contact for each row of source regions in the second direction, and a source line connected to said row of source regions.

Although FIG. 8 shows example blocks of process 1200, in some implementations, process 1200 may include additional blocks, fewer blocks, different blocks, or differently arranged blocks than those depicted in FIG. 8. Additionally, or alternatively, two or more of the blocks of process 1200 may be performed in parallel.

The process flow in accordance with embodiments of the present invention can be applied to other back-end-of-line (BEOL) memory, including but not limited to, Conductive-Bridge RAM (CBRAM), Magnetic RAM (MRAM), Ferroelectric RAM (FeRAM), and Phase Change RAM (PCRAM).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. Other embodiments may have layers in different orders, additional layers or fewer layers than the illustrated embodiments.

Various operations are described as multiple discrete operations, in turn, in a manner that is most helpful in understanding the present invention, however, the order of description should not be construed to imply that these operations are necessarily order dependent. In particular, these operations need not be performed in the order of presentation.

The terms “over,” “above” “under,” “between,” and “on” as used herein refer to a relative position of one material layer or component with respect to other layers or components. For example, one layer deposited above or over or under another layer may be directly in contact with the other layer or may have one or more intervening layers. Moreover, one layer deposited between two layers may be directly in contact with the two layers or may have one or more intervening layers. In contrast, a first layer “on” a second layer is in direct contact with that second layer. Similarly, unless explicitly stated otherwise, one feature deposited between two features may be in direct contact with the adjacent features or may have one or more intervening layers.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. The terms “first,” “second,” “third,” “fourth,” etc. as used herein are meant as labels to distinguish among different elements and may not necessarily have an ordinal meaning according to their numerical designation.

1. An access transistor array for a memory device, comprising:
a plurality of active areas (AA) formed on a substrate, each AA comprising a drain region and a source region arranged in a first direction (Y), and a polysilicon gate (POs) extending in a second direction (X) across the AA and separating the drain region and source region,
wherein adjacent source regions in the second direction are connected, and adjacent drain regions in the second direction are separated by a shallow trench isolation (STI).

2. The access transistor array of claim 1, wherein each drain region comprises a drain contact, and adjacent source regions in the second direction share a same source contact.

3. The access transistor array of claim 1, wherein each drain contact in adjacent drain regions in the first direction is connected to a bit line through a resistive random-access memory (RRAM) stack, and adjacent source regions in the second direction are connected to the same source contact through a source line.

4. The access transistor array of claim 3, wherein a length of the source region in the first direction is smaller than a length of the drain region in the first direction by at least 10%.

5. The access transistor array of claim 3, wherein a length of the source region in the first direction is smaller than a length of the drain region in the first direction by at least 20%.

6. The access transistor array of claim 3, wherein the bit line is perpendicular to the source line.

7. The access transistor array of claim 3, wherein a distance between two adjacent POs sandwiching a source region is smaller than two adjacent POs sandwiching a drain region by at least 10%.

8. The access transistor array of claim 3, wherein a distance between two adjacent POs sandwiching a source region is smaller than two adjacent POs sandwiching a drain region by at least 20%.

9. The access transistor array of claim 1, wherein the memory device is a back-end-of-line (BEOL) memory.

10. The access transistor array of claim 1, wherein the memory device is a resistive random-access memory (RRAM).

11. The access transistor array of claim 1, wherein the source line is connected to a first metal layer in the memory device that is closest to the substrate.

12. The access transistor array of claim 11, further comprising a word line, wherein the word line is configured to be parallel to the source line.

13. A method of manufacturing a memory device, comprising:
formatting a plurality of active areas on a substrate, each AA comprising a drain region and a source region arranged in a first direction (Y);
forming a polysilicon gate (POs) extending in a second direction (X) across the AA and separating the drain region and source region;
forming a shallow trench isolation (STI) extending in a first direction separating adjacent drain regions in the second direction;
forming wherein adjacent source regions in the second direction are connected, and adjacent drain regions in the second direction are separated by a shallow trench isolation (STI); and
forming a memory device above the substrate.

14. The method of claim 13, further comprising:
forming a drain contact in each of the drain region, and a bit line connected to each drain contact through a resistive random-access memory (RRAM) stack.

15. The method of claim 13, further comprising:
forming a source contact for each row of source regions in the second direction, and a source line connected to said row of source regions.

16. An access transistor array for a memory device, comprising:
a plurality of active areas (AA) formed on a substrate, each AA comprising a drain region and a source region arranged in a first direction (Y), and a polysilicon gate (POs) extending in a second direction (X) across the AA and separating the drain region and source region;
wherein adjacent drain regions in the second direction are connected, and adjacent source regions in the second direction are separated by a shallow trench isolation (STI).

17. The access transistor array of claim 16, wherein each source region comprises a source contact, and adjacent drain regions in the second direction share a same drain contact.

18. The access transistor array of claim 16, wherein source contacts in adjacent source regions in the first direction are connected to a source line, and adjacent drain regions in the second direction are connected to the same drain contact through a drain line.

19. The access transistor array of claim 18, wherein a length of the drain region in the first direction is smaller than a length of the source region in the first direction by at least 10%.

20. The access transistor array of claim 18, wherein a length of the drain region in the first direction is smaller than a length of the source region in the first direction by at least 20%.
